(19) United States
(12) Patent Application Publication
(10) Pub. No.: US 2026/0016526 A1
(43) Pub. Date: Jan. 15, 2026

(54) APPARATUS AND METHOD FOR INSPECTING ORGANIC LIGHT-EMITTING DISPLAY APPARATUS

(71) Applicant: Samsung Display Co., Ltd., Yongin-si (KR)

(72) Inventors: JAE CHUL HONG, Yongin-si (KR); YOONSU KANG, Yongin-si (KR); EUNKYEONG CHA, Yongin-si (KR)

(73) Assignee: Samsung Display Co., Ltd., Yongin-si (KR)

(21) Appl. No.: 19/098,175

(22) Filed: Apr. 2, 2025

(30) Foreign Application Priority Data
Jul. 10, 2024 (KR) 10-2024-0091104

(51) Int. Cl. G01R 31/26; G01R 27/26; G01R 31/27

(52) U.S. Cl. CPC G01R 31/2635; G01R 27/26; G01R 31/27

(57) ABSTRACT

Provided is an inspecting apparatus for an organic light-emitting display apparatus, including a connector including an inspection pad electrically connected to a signal pad of a display panel included in a glass panel, a panel driver electrically connected to the connector and supplying a driving signal for driving the display panel, and an impedance meter electrically connected to the connector and that measures the impedance of an organic light-emitting device included in the display panel.

### CROSS-REFERENCE TO RELATED APPLICATION(S)

This application claims priority to and benefits of Korean Patent Application No. 10-2024-0091104 under 35 USC § 119, filed on Jul. 10, 2024, in the Korean Intellectual Property Office, the entire contents of which are incorporated herein by reference.

### BACKGROUND

### 1. Technical Field

Embodiments relate to an apparatus and method for inspecting an organic light-emitting display apparatus.

### 2. Description of the Related Art

The organic light-emitting display apparatus includes an organic light-emitting device including a hole injection electrode, an electron injection electrode, and an organic emission layer formed therebetween, and holes injected from the hole injection electrode are combined with electrons injected from the electron injection electrode in the organic emission layer to form excitons, which are transitioned from an excited state to a ground state, thereby generating light.

Organic light-emitting display apparatuses, which are self-luminous display apparatuses, do not require a separate light source. Thus, organic light-emitting display apparatuses can be driven at low voltage and can be configured in a lightweight and thin form. Organic light-emitting display apparatuses have high-quality characteristics such as wide viewing angle, high contrast, and fast response speed, and thus, attract attention as a next-generation display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide an inspecting apparatus and method that can inspect the impedance of an organic light-emitting device in a glass panel state.

Additional aspects will be set forth in part in the description which follows and, in part, will be apparent from the description, or may be learned by practice of the presented embodiments.

An embodiment may include an inspecting apparatus for an organic light-emitting display apparatus including a connector including an inspection pad electrically connected to a signal pad of a display panel included in a glass panel; a panel driver electrically connected to the connector to supply a driving signal to drive the display panel; and an impedance meter electrically connected to the connector to measure an impedance of an organic light-emitting device included in the display panel.

In an embodiment, the organic light-emitting device may include a first electrode, an interlayer, and a second electrode, and the impedance meter may be electrically connected to the first electrode and the second electrode of the organic light-emitting device to measure the impedance of the interlayer of the organic light-emitting device.

In an embodiment, the impedance meter may measure the impedance by applying a measurement direct current signal and a measurement alternating current signal to the organic light-emitting device.

In an embodiment, the impedance meter may include a measurement member that applies the measurement alternating current signal and obtains an impedance corresponding to the measurement alternating current signal, a source member that applies the measurement direct current signal, and a bias tee that connects the measurement member and the source member to the connector.

In an embodiment, the bias tee may provide a combination of the measurement alternating current signal and the measurement direct current signal to the organic light-emitting device.

In an embodiment, a controller may determine whether the display panel is defective based on the obtained impedance.

In an embodiment, the controller may calculate an impedance parameter of the organic light-emitting device from the impedance and determine whether the display panel is defective by using the calculated impedance parameter.

In an embodiment, the impedance parameter may be defined as the maximum value in a graph showing the real part of the impedance of the organic light-emitting device as a function of voltage.

In an embodiment, the controller may determine whether the display panel is defective by using an amount of change in the impedance parameter according to aging.

In an embodiment, the impedance meter may measure the impedance of the organic light-emitting device before being cut into display panel units after the organic light-emitting device is completed on the glass panel.

An embodiment may include a method of inspecting an organic light-emitting display apparatus, the method including electrically connecting a signal pad of a display panel included in a glass panel to an inspection pad included in a connector; applying a driving signal to the display panel through a panel driver electrically connected to the connector; measuring the impedance of an organic light-emitting device included in the display panel by using an impedance meter electrically connected to a connector; and determining whether the display panel is defective based on the measured impedance.

In an embodiment, the organic light-emitting device may include a first electrode, an interlayer, and a second electrode, and the impedance meter may be electrically connected to the first electrode and the second electrode of the organic light-emitting device to measure the impedance of the interlayer of the organic light-emitting device.

In an embodiment, the impedance meter may measure the impedance by applying a measurement direct current signal and a measurement alternating current signal to the organic light-emitting device.

In an embodiment, the impedance meter may include a measurement member that applies the measurement alternating current signal and obtains an impedance corresponding to the measurement alternating current signal, a source member that applies the measurement direct current signal, and a bias tee that connects the measurement member and the source member to the connector.

In an embodiment, the bias tee may provide a combination of the measurement alternating current signal and the measurement direct current signal to the organic light-emitting device.

In an embodiment, the determining whether the display panel is defective may include calculating an impedance parameter of the organic light-emitting device from the impedance, and determining whether the display panel is defective by using the calculated impedance parameter.

In an embodiment, the impedance parameter may be defined as the maximum value in a graph showing the real part of the impedance of the organic light-emitting device as a function of voltage.

In an embodiment, whether the display panel is defective may be determined based on an amount of change in the impedance parameter according to aging.

In an embodiment, the determining whether the display panel is defective may include sequentially obtaining the impedance parameter from a plurality of sequentially deposited glass panels; and determining that the display panel included in a corresponding glass panel is defective in case that the impedance parameter deviates from a given reference value.

In an embodiment, the measuring the impedance of the organic light-emitting device may be performed before being cut into display panel units after the organic light-emitting device is completed on the glass panel.

Other aspects, features and advantages in addition to those described above will become apparent from the following drawings, claims and detailed description of the disclosure.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic plan view illustrating an inspecting apparatus for an organic light-emitting display apparatus according to an embodiment;

FIG. 2 shows a schematic diagram of an equivalent circuit of a pixel included in a display panel;

FIG. 3 shows a schematic diagram illustrating a schematic cross-sectional view of a pixel according to an embodiment;

FIG. 4 shows a schematic diagram showing the configuration of an impedance meter;

FIG. 5A shows a schematic diagram of an equivalent circuit of an organic light-emitting device included in a pixel;

FIG. 5B is a graph showing the real part of capacitance and impedance with respect to the voltage of an organic light-emitting device;

FIG. 5C is a graph showing the real part of impedance with respect to the voltage of an organic light-emitting device;

FIG. 6 is a flowchart showing the manufacturing process of an organic light-emitting display apparatus step by step;

FIG. 7 is a flowchart illustrating a method of inspecting an organic light-emitting display apparatus according to an embodiment;

FIG. 8 is a graph showing the change in the impedance real part according to the incorporation of impurities;

FIGS. 9A and 9B are graphs showing the change in the real part of impedance according to aging;

FIGS. 10A, 10B, 10C, 10D, and 10E are schematic diagrams for explaining a pixel lateral current of an organic light-emitting device;

FIGS. 11A and 11B are graphs showing the change in the real part of impedance according to a pixel lateral current caused by a change in a panel process;

FIGS. 12A and 12B are graphs showing the change in the real part of impedance according to the pixel lateral current generated by changing a p-type doping concentration;

FIG. 13 is a graph showing the results of time-series monitoring of the change in the real part of impedance according to aging; and

FIG. 14 is a graph showing the results of monitoring the occurrence of pixel lateral current to time series.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

Since the disclosure can be modified in various ways and can have various embodiments, given embodiments will be illustrated in the drawings and described in detail in the detailed description. The effects and features of the disclosure and methods for achieving them will become clear by referring to the embodiments described in detail below along with the drawings. However, the disclosure is not limited to the embodiments disclosed below and may be implemented in various forms.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the following embodiments, when a unit, an area, or a component, etc. is described to be on another unit, another area, or another component, it is not only a case where a unit, an area, or a component is directly on another unit, another area, or another component, but also when other units, other areas, other components, etc. are disposed therebetween.

In the following embodiments, terms such as “connect” or “couple” do not necessarily refer to a direct and/or fixed connection or coupling of two members, unless the context clearly indicates otherwise, and do not exclude a case where another member is located between two members.

In the drawings, the sizes of components may be exaggerated or reduced for convenience of explanation. For example, the size and/or thickness of each component shown in the drawings are arbitrarily shown for convenience of explanation, and the disclosure is not necessarily limited to what is shown.

In cases where an embodiment can be implemented differently, a given process sequence may be performed differently from the described order. For example, two processes described in succession may be performed substantially at the same time, or may be performed in an order opposite to that in which the processes are described.

Hereinafter, embodiments will be described in detail with reference to the accompanying drawings. When describing with reference to the drawings, identical or corresponding components will be assigned the same reference numerals and redundant description thereof may be omitted.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

In this specification, an organic light-emitting display apparatus may refer to a display apparatus including an organic light-emitting device (organic light-emitting device).

In this specification, a glass panel may refer to a mother glass that lays the groundwork for display production and may also be referred to as a mother glass panel.

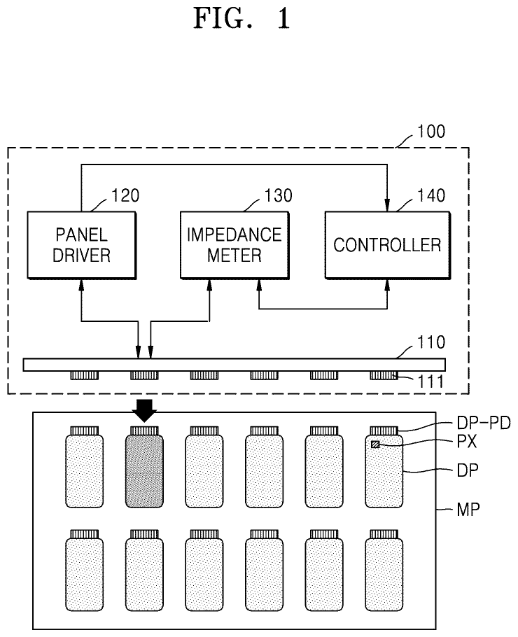

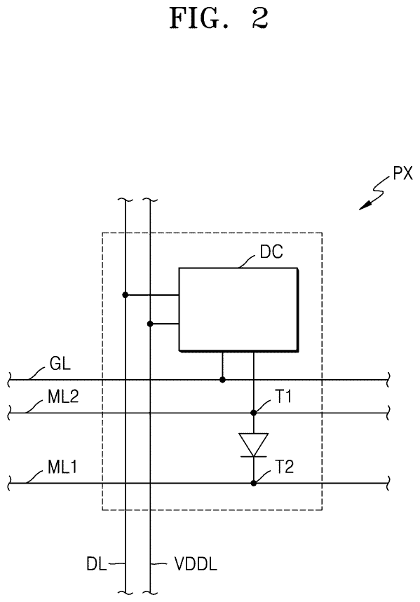

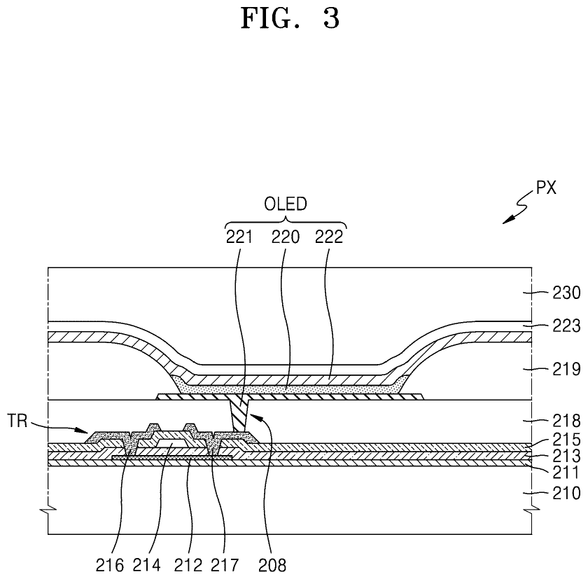

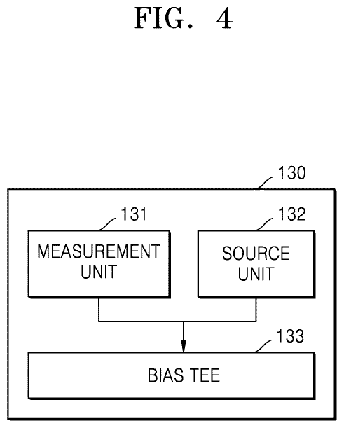

FIG. 1 is a schematic plan view illustrating an inspecting apparatus 100 for an organic light-emitting display apparatus according to an embodiment, FIG. 2 shows a schematic diagram of an equivalent circuit of a pixel PX included in a display panel DP, FIG. 3 shows a schematic diagram illustrating a schematic cross-sectional view of a pixel PX according to an embodiment, and FIG. 4 shows a schematic diagram showing the configuration of an impedance meter 130.

Referring to FIGS. 1 to 4, the inspecting apparatus 100 according to an embodiment may include a connector 110, a panel driver 120, and an impedance meter 130, and a controller 140. The inspecting apparatus 100 may be connected to a display panel DP including an organic light-emitting device included in the mother glass panel MP and may be capable of measuring the impedance of the organic light-emitting device. While being in the mother glass panel MP, the inspection on whether the display panels DP are defective, can be performed.

The mother glass panel MP may include display panels DP. Each of the display panels DP may include a display part including a pixel PX and a signal pad DP-PD provided outside the display part.

The pixel PX may include an organic light-emitting device and a pixel driver DC that drives the organic light-emitting device. Pixels PX may be provided, and the pixels PX may be arranged (or disposed) in various pattern, such as a stripe structure or a PENTILET^{M} structure.

Each of the pixels PX may include at least one organic light-emitting device, and each pixel PX may emit red (R) light, green (G) light, blue B light, or white (W) light. Accordingly, the display panel DP in which pixels PX are arranged (or disposed) may display various color images.

The pixel driver DC may be connected to a power supply line VDDL, a gate line GL to which gate signals are supplied, and a data line DL to which data voltages are supplied. The pixel driver DC may include thin film transistors and a capacitor. Thin film transistors may adjust the brightness of each pixel PX by adjusting the amount of current flowing through the organic light-emitting device according to the data voltage provided from the data line DL.

The organic light-emitting device may be connected to a first measurement line ML1 and a second measurement line ML2. The first measurement line ML1 may be connected to a cathode terminal T2 of the organic light-emitting device, and the second measurement line ML2 may be connected to an anode terminal T1 of the organic light-emitting device.

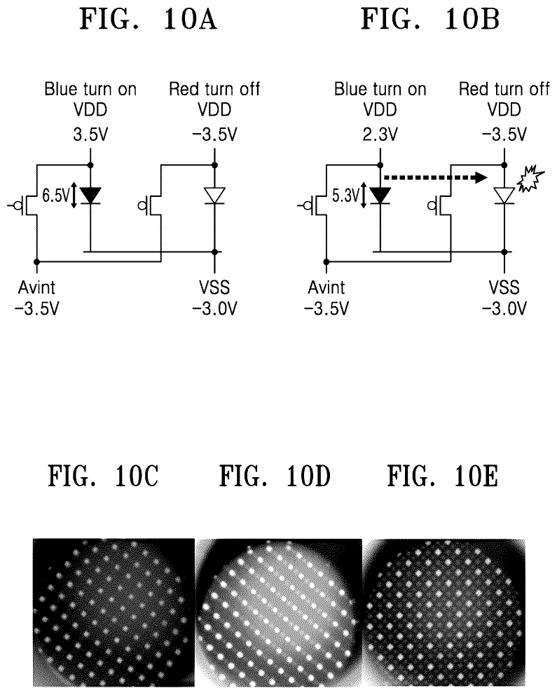

The first measurement line ML1 and the second measurement line ML2 may be connected to the impedance meter 130 through the connector 110. Accordingly, the inspecting apparatus 100 may measure the impedance of the organic light-emitting device included in the pixel PX. The first measurement line ML1 may also supply a low potential voltage VSS (referring as FIG. 10A or FIG. 10B) to the organic light-emitting device.

The signal pad DP-PD may include terminals connected to the power supply line VDDL, the data line DL, the gate line GL, the first measurement line ML1, and the second measurement line ML2. The signal pad DP-PD may connect various wires electrically connected to the pixel PX with external devices.

As shown in FIG. 3, an organic light-emitting device and a thin film transistor TR which constitute the pixel PX may be formed on a substrate 210. The substrate 210 may include glass, plastic, or metal. The substrate 210 may be a flexible substrate.

A buffer layer 211 may be formed on the substrate 210. The buffer layer 211 may provide a flat surface to the upper part of the substrate 210 and may include an insulating material to prevent moisture and foreign substances from penetrating toward the substrate 210.

A thin film transistor TR, a capacitor (not shown), and an organic light-emitting device OLED may be formed on the buffer layer 211. The thin film transistor TR may include an active layer 212, a gate electrode 214, a source electrode 216, and a drain electrode 217.

The organic light-emitting device OLED may include a first electrode 221, a second electrode 222, and an interlayer 220 provided between the first electrode 221 and the second electrode 222. The first electrode 221 may be an anode, and may be electrically connected to the anode terminal T1 of FIG. 2. Accordingly, the first electrode 221 may be electrically connected to the impedance meter 130 through the connector 110. The second electrode 222 may be a cathode, and may be connected to the cathode terminal T2 of FIG. 2. Accordingly, the second electrode 222 may be electrically connected to the impedance meter 130 through the connector 110.

By way of example, the active layer 212 formed in a pattern may be disposed on the upper surface of the buffer layer 211. The active layer 212 may be formed to include various materials. For example, the active layer 212 may include an inorganic semiconductor material such as amorphous silicon or crystalline silicon. In an embodiment, the active layer 212 may include an oxide semiconductor. In an embodiment, the active layer 212 may include an organic semiconductor material.

A gate insulating film 213 may be formed on the active layer 212. A gate electrode 214 may be formed on the gate insulating film 213 to correspond to the active layer 212. An interlayer insulating film 215 may be formed to cover the gate electrode 214, and the source electrode 216 and the drain electrode 217 may be formed on the interlayer insulating film 215 while being in contact a given area of the active layer 212. A planarization film 218 may be formed to cover the source electrode 216 and the drain electrode 217, and a separate insulating film may be further formed on the planarization film 218.

The first electrode 221 may be formed on the planarization film 218. The first electrode 221 may be formed to be electrically connected to either the source electrode 216 or the drain electrode 217 through a through hole 208.

Additionally, a pixel defining layer 219 may be formed to cover the first electrode 221. For example, the pixel defining layer 219 may include a photosensitive organic insulating material such as black resin, graphite powder, gravure ink, black spray, or black enamel. After forming an opening in the pixel defining layer 219, the interlayer 220 including an organic emission layer may be formed in an area defined by the opening. The pixel defining layer 219 may define a pixel area and a non-pixel area. For example, the opening of the pixel defining layer 219 becomes the actual pixel area.

The interlayer 220 may include an organic emission layer. In an optional embodiment, the interlayer 220 may include an organic emission layer and, at least one of a hole injection layer (HIL), a hole transport layer, an electron transport layer, and an electron injection layer. The embodiment is not limited to the embodiment, and the interlayer 220 may include an organic emission layer and may further include various other functional layers.

The second electrode 222 may be formed on the interlayer 220. The first electrode 221 may be patterned for each pixel, and the second electrode 222 may be formed in such a manner that a common voltage is applied to all pixels.

Although only one organic light-emitting device OLED is shown in the drawing, a display panel DP may include organic light-emitting devices. One pixel may be formed for each organic light-emitting device OLED, and each pixel may implement a color of red, green, blue, or white.

However, the disclosure is not limited to the embodiment. The interlayer 220 may be commonly formed throughout the planarization film 218 regardless of the location of a pixel. In this regard, the organic emission layer may be formed by vertically stacking or mixing layers including light-emitting materials that emit red, green, and blue light, for example. In an embodiment, as long as white light is emitted, other colors of light may be combined. A color conversion layer or a color filter that converts the emitted white light into a given color may be further provided.

The protective layer 223 may be disposed on the organic light-emitting device OLED and the pixel defining layer 219, and may cover and protect the organic light-emitting device OLED. The protective layer 223 may use an inorganic insulating film and/or an organic insulating film.

An encapsulation film 230 may prevent external moisture or oxygen from penetrating into the organic light-emitting device OLED and/or the thin film transistor TR. The encapsulation film 230 may include an inorganic film and/or an organic film. The encapsulation film 230 may have a structure in which inorganic films and organic films are alternately stacked with each other, but is not limited thereto. The encapsulation film 230 may be a single film or a stacked film. In an embodiment, the encapsulation film 230 may include a low-melting-point glass material including tin oxide.

As for an organic light-emitting device, emission characteristics, such as brightness and chromaticity, may vary depending on the characteristics of the materials that make up the device and the structure of the device. An organic light-emitting device includes a stacked structure of materials with different electronic properties, and the driving characteristics thereof vary depending on a constant voltage or a given current and frequency. For example, an organic light-emitting device has different device characteristics depending on the surface state of each electrode (for example, the first electrode 221 and the second electrode 222), exposure to foreign substances, the thickness and position of each organic emission layer, or the doping amount of the dopant.

Therefore, even in case that the same organic light-emitting device is driven with the same voltage, the type of the current signal may greatly vary due to the difference in impedance Z of the organic light-emitting device. These characteristics of the organic light-emitting device also affect the efficiency and lifespan of the display panel DP, which causes defects in the display panel DP.

Accordingly, embodiments can confirm the exact characteristics of the organic light-emitting device by measuring the impedance Z of the organic light-emitting device and determine whether the display panel DP is defective.

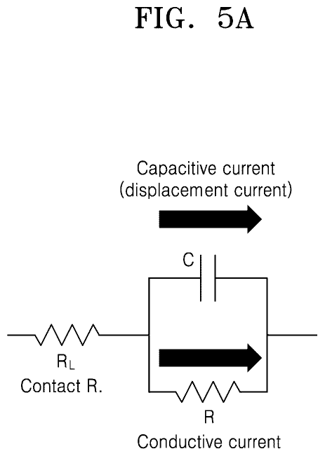

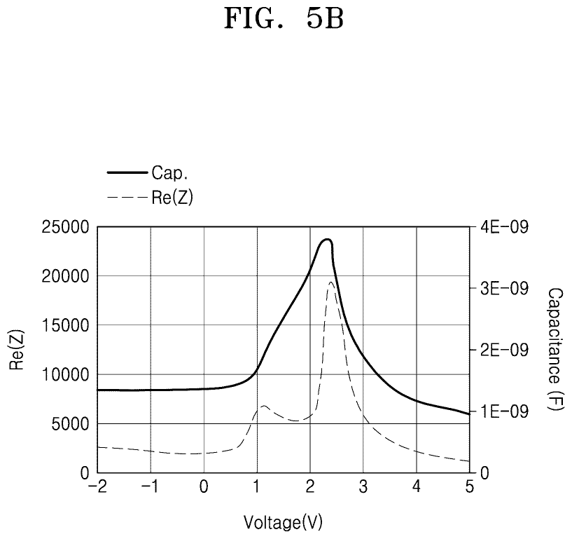

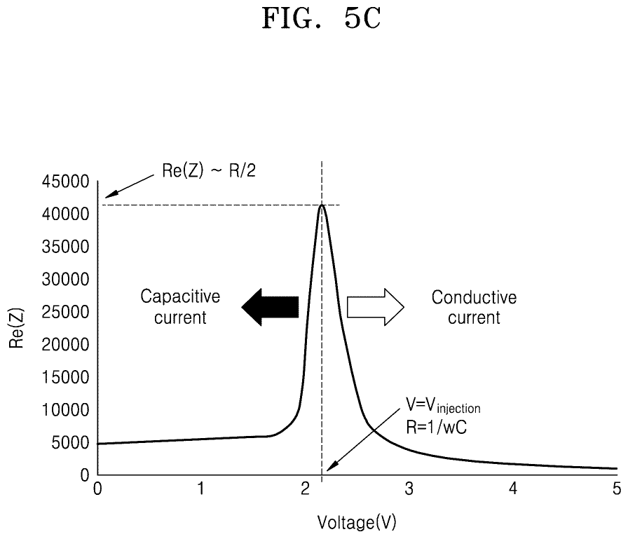

Hereinafter, the impedance parameters corresponding to the light emission characteristics of the organic light-emitting device will be described in detail with reference to FIGS. 5A to 5C.

FIG. 5A is a schematic diagram of an equivalent circuit of an organic light-emitting device included in the pixel PX, and FIG. 5B shows the graph of the capacitance C and the impedance real part Re(Z) of the voltage of the organic light-emitting device, and FIG. 5C is a graph showing the impedance real part Re(Z) with respect to the voltage of an organic light-emitting device.

Referring to FIG. 5A, in an organic light-emitting device, an insulator of an organic film, which is an interlayer, is disposed between two metal electrodes. In case that expressed as an equivalent circuit, the organic light-emitting device may be expressed as a parallel circuit of a resistor and a capacitor. In case that a given direct current voltage and an alternating current voltage of a given frequency (w) are applied to such an organic light-emitting device, the impedance Z may be calculated as shown in Equation 1.

$$\frac{1}{Z} = \frac{1}{R} + \frac{1}{\frac{1}{iwC}} = \frac{1}{R} + iwC \qquad [ Equation 1 ]$$

$$Z = \frac{R}{1 + {w}^{2} {R}^{2} {C}^{2}} - i \frac{{wR}^{2} C}{1 + {w}^{2} {R}^{2} {C}^{2}} = Re ( Z ) + i Im ( Z )$$

In this regard, Re(Z) refers to the real part of impedance Z, and Im(Z) refers to the imaginary part of impedance Z.

An organic light-emitting device has a contact resistance (R_{L}) due to an electrode connected to an internal organic layer circuit and a backplane BP, and the impedance Z and the impedance real part Re(Z) of the organic light-emitting device may be expressed as Equation 2.

$$Z = {R}_{L} + \frac{R}{1 + {w}^{2} {R}^{2} {C}^{2}} - i \frac{{wR}^{2} C}{1 + {w}^{2} {R}^{2} {C}^{2}} \qquad [ Equation 2 ]$$

$$Re ( Z ) = {R}_{L} + \frac{R}{1 + {w}^{2} {R}^{2} {C}^{2}}$$

Therefore, in case that measuring the capacitance C or impedance Z of an organic light-emitting device, a measurement value that includes the influence of the backplane may be obtained together with the desired characteristics of the organic light-emitting device. By way of example, capacitance C may be greatly influenced by the capacitance of the transistor of the backplane circuit part and wiring resistance.

In the case of impedance Z, a parameter not affected by the influence of the backplane may be extracted. By way of example, as shown in FIG. 5B, as the voltage increases, due to the capacitive current flowing toward the capacitor C, the capacitance (Cap.) and the impedance real part Re(Z) may all be increased to the maximum value, and are rapidly decreased as the charge disappears after light is emitted.

In this regard, with reference to the graph of the impedance real part Re(Z) according to voltage, it is confirmed that two or more peaks are formed, unlike the graph of capacitance C according to voltage. From the result, it can be seen that the first charge injection occurred at the first peak of the graph of the impedance real part Re(Z) according to voltage; and the second charge injection occurred and light was emitted at the second peak.

Therefore, by analyzing the graph of the impedance real part Re(Z) according to voltage for an organic light-emitting device, the performance of charge injection and light emission can be analyzed based on the peak value, and the impedance real part Re(Z) can be used as an impedance parameter corresponding to the light emission characteristics of an organic light-emitting device.

The maximum value (Re(Z)max) of the real part of impedance may be derived as in Equation 3.

$$\frac{d Re ( Z )}{dR} = 0 , {R}_{max} ≅ \frac{1}{wC} \qquad [ Equation 3 ]$$

$${Re ( Z )}_{max} ≅ {R}_{L} + \frac{R}{2} ≅ \frac{R}{2}$$

For example, as shown in FIG. 5C, it can be seen that, from the point in case that the impedance real part Re(Z) reaches the maximum value, the external resistance component (R_{L}) is ignored, and the impedance Z inside the device becomes dominant. In other words, from the point in case that the impedance real part Re(Z) reaches its maximum value, the resistance component (R_{L}) outside the device, may be distinguishable from the resistance R and capacitance C components in the device, and after that point, the impedance real part Re(Z) changes in value due to alternating current resistance components such as impurities or material deterioration.

Therefore, the maximum value (Re(Z)ₘₐₓ) of the impedance real part may be used as an impedance parameter that is used to analyze the characteristics of an organic light-emitting device. By way of example, organic light-emitting devices are very sensitive to changes in characteristics even in case that organic materials include very fine impurities, foreign substances are present on the surface of each electrode (for example, the first electrode 221 and the second electrode 222), or surface roughness is large. Embodiments enable monitoring of defects in the display panel DP that occur during the mass production process by selecting an impedance parameter that can well reflect each characteristic of the organic light-emitting device.

Referring again to FIG. 1, the connector 110 may be disposed between the display panel DP and the impedance meter 130 on one side or a side of the mother glass panel MP, and may be connected to the display panel DP and the panel driver 120 and the impedance meter 130. The connector 110 may provide various signals supplied from the panel driver 120 to the display panel DP. Additionally, the connector 110 may electrically connect the display panel DP included in the mother glass panel MP to the impedance meter 130. The panel driver 120 and the impedance meter 130 may be connected to the connector 110 via a cable.

The connector 110 may include an inspection pad 111 that is electrically connected to the signal pad DP-PD of the display panel DP. The inspection pad 111 may be provided to directly contact the signal pad DP-PD. The location and/or number of inspection pads 111 may be determined in correspondence to the signal pads DP-PD on the mother glass panel MP. For example, the inspection pad 111 may be arranged (or disposed) to overlap the signal pad DP-PD, and the number of inspection pads 111 may be the same as the number of signal pads DP-PD.

The panel driver 120 may be connected to the display panel DP through the connector 110. The panel driver 120 may be used to drive the display panel DP and may include a power driver, a data driver, and a gate driver. The power driver may supply the high potential voltage VDD (referring as FIG. 10A or FIG. 10B) and the low potential voltage VSS to be applied to the pixel PX to the power supply line VDDL and the second measurement line ML2, respectively. The data driver may supply a data voltage to the data line DL, and the gate driver may supply a gate signal to the gate line GL.

The panel driver 120 may drive pixels PX individually or in groups. For example, the panel driver 120 may group and drive only pixels that emit red (R) among pixels PX. In an embodiment, the panel driver 120 may group and drive only a few pixels in a given area among the pixels PX.

In case that measuring the impedance of an organic light-emitting device, the panel driver 120 may set the high potential voltage VDD, the low potential voltage VSS, the data voltage, and the gate signal in such a manner that the pixel driver DC does not make an influence thereon. In an embodiment, the data voltage may be lower than the saturation voltage of the driving thin film transistor (not shown) of the pixel driver DC.

The impedance meter 130 may be connected to the display panel DP through the connector 110 and may measure the impedance of the organic light-emitting device included in the display panel DP. In an embodiment, the impedance meter 130 may be electrically connected to the first measurement line ML1 and the second measurement line ML2 of the organic light-emitting device through the connector 110. Accordingly, the impedance meter 130 may be electrically connected to the anode terminal T1 and the cathode terminal T2 of the organic light-emitting device. In other words, the anode terminal T1 and cathode terminal T2 of the organic light-emitting device may be connected to the impedance meter 130 via the signal pad DP-PD of the display panel DP and the inspection pad 111 of the connector 110.

The impedance meter 130 may input a measurement signal to the organic light-emitting device and obtain a detection signal from the organic light-emitting device formed in correspondence to the measurement signal, and measure the impedance of the organic light-emitting device. The measurement signal applied by the impedance meter 130 may include both direct current signals and alternating current signals. As shown in FIG. 4, the impedance meter 130 may include a measurement unit 131, a source unit 132, and a bias tee 133.

The measurement unit 131 may apply a measurement alternating current signal between the anode terminal T1 and the cathode terminal T2 of the organic light-emitting device. In an embodiment, the measurement unit 131 may obtain a detection signal output from the organic light-emitting device in response to the measurement alternating current signal. In this regard, the measurement alternating current signal may be an alternating voltage with a given amplitude and frequency, and the detection signal may be an alternating current, but the measurement alternating current signal and the detection signal are not limited thereto. In an embodiment, the measurement unit 131 may calculate the impedance of the organic light-emitting device using the obtained detection signal. In an embodiment, the measurement unit 131 may be an LRC meter, but is not limited thereto.

The source unit 132 may apply a measurement direct current signal between the anode terminal T1 and the cathode terminal T2 of the organic light-emitting device. In this regard, the measurement direct current signal may be a direct current having a given magnitude. The source unit 132 may generate a current signal corresponding to the organic light-emitting device to be inspected and provide the current signal to the organic light-emitting device. For example, the source unit 132 may be a source measurement device that can apply a voltage or a current to an organic light-emitting device and measure current-voltage-brightness (IVL) characteristics, but is not limited thereto.

The bias tee 133 may be connected to the measurement unit 131 and the source unit 132. The measurement alternating current signal and the measurement direct current signal output from the measurement unit 131 and the source unit 132 may be provided to the bias tee 133. The bias tee 133 may overlap the measurement alternating current signal applied by the measurement unit 131 and the measurement direct current signal applied by the source unit 132 and provide the overlapping signal to the organic light-emitting device. In this regard, the bias tee 133 may combine the measurement alternating current signal and the measurement direct current signal at a given ratio and provide the same to the organic light-emitting device.

By way of example, the bias tee 133 may adjust the ratio of the measurement alternating current signal and the measurement direct current signal in response to the resistance range or impedance range of the display panel DP which varies depending on the size of the display panel DP, the type and number of organic light-emitting devices included in the display panel DP, etc., and combine the adjusted ratio of the measurement alternating current signal and the measurement direct current signal, and the measurement alternating current signal and the measurement direct current signal which are combined may be provided to the organic light-emitting device.

For example, since the impedance meter 130 includes the source unit 132 that generates various ranges of measurement direct current signals and combines the measurement alternating current signal and the measurement direct current signal via the bias tee 133 and provides the combination to the organic light-emitting device, various sizes and types of the display panel DP and the mother glass panel MP may be able to be measured. Since the impedance meter 130 includes the source unit 132 and the bias tee 133, a measurement signal in response to various problems that occur during the mass production of the display panel DP may be generated and a detection signal with improved accuracy may be obtained.

The controller 140 may be connected to the panel driver 120 and the impedance meter 130. The controller 140 may set various signal values of the panel driver 120. The brightness of the organic light-emitting device may be controlled according to the set value of the panel driver 120, and to achieve the desired brightness, the controller 140 may adjust the set value of the panel driver 120 to allow a given voltage or current to be applied to an organic light-emitting device.

In an embodiment, the controller 140 may set the values of the measurement alternating current signal and the measurement direct current signal which are provided by the impedance meter 130 to the organic light-emitting device. For example, the controller 140 may set the size and frequency of the measurement alternating current signal, the size of the measurement direct current signal, or the combination ratio of the measurement alternating current signal and the measurement direct current signal.

In an embodiment, the controller 140 may process the impedance measured by the impedance meter 130. In an embodiment, the controller 140 may calculate an impedance parameter by using the impedance measured by the impedance meter 130 and determine whether the display panel DP is defective based on the calculated impedance parameter. In an embodiment, the controller 140 may generate and provide a result report regarding detected defects in the display panel DP.

In an embodiment, the controller 140 may monitor defects in the display panel DP during mass production, by using impedance parameters. In the case where a defect is detected during monitoring, the controller 140 may provide an alarm or feedback to a preset process line.

The inspecting apparatus 100 for an organic light-emitting display apparatus according to embodiments can measure an impedance in case that the first electrode 221, the interlayer 220, and the second electrode 222 of the organic light-emitting device OLED are formed and a charge is applicable to the first electrode 221 and the second electrode 222. For example, the inspecting apparatus 100 may measure the impedance of the organic light-emitting device before being cut into display panel DP units after the organic light-emitting device is completed on the mother glass panel MP.

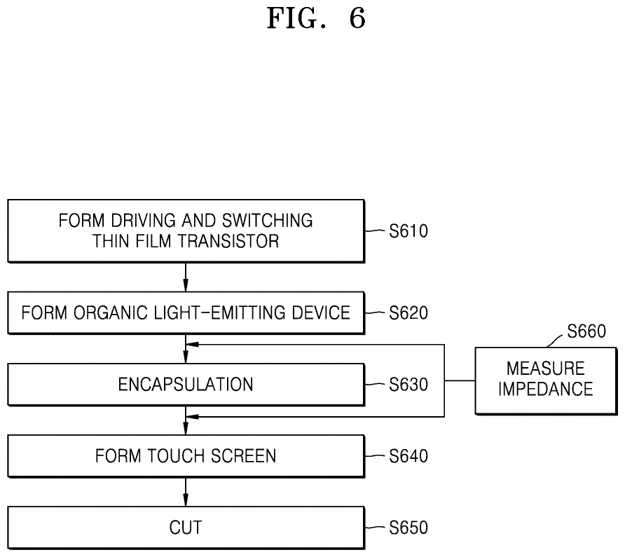

FIG. 6 is a flowchart showing the manufacturing process of an organic light-emitting display apparatus step by step.

Referring to FIG. 6 along with FIG. 3, first, the buffer layer 211 may be formed on the substrate 210, and a switching and driving thin film transistor TR may be formed (S610).

For example, the active layer 212 may be formed on the buffer layer 211, and the switching and driving thin film transistor TR including the gate insulating film 213, the gate electrode 214, the interlayer insulating film 215, the source electrode 216, and the drain electrode 217, may be formed. The planarization film 218 may be formed to cover the source electrode 216 and the drain electrode 217.

An organic light-emitting device OLED may be formed on the planarization film 218 (S620).

The organic light-emitting device OLED may be formed by sequentially depositing the first electrode 221, the interlayer 220, and the second electrode 222. By way of example, the first electrode 221 may be formed to contact one of the source electrode 216 and the drain electrode 217 through the through hole 208. A photosensitive organic insulating material may be applied on the first electrode 221 and patterned to form the pixel defining layer 219.

An organic light-emitting material may be applied or deposited on the opening of the pixel defining layer 219 to form the interlayer 220. In this regard, the interlayer 220 may be configured as a single layer consisting of a light-emitting material. In an embodiment, to increase light emission efficiency, the interlayer 220 may be configured as a multilayer including a hole injection layer (HIL), a hole transport layer, an organic emission layer, an electron transport layer, and an electron injection layer.

The second electrode 222 in which a transparent conductive material is deposited in a great thickness on a metal film including a metal material with a low work function deposited, is formed on the interlayer 220, thereby completing manufacture of the organic light-emitting device.

The organic light-emitting device OLED is encapsulated (S630).

Encapsulation is intended to cover and protect the organic light-emitting device OLED, and may be formed by laminating and curing the protective layer 223 and/or an encapsulation film 230 on the organic light-emitting device.

A touch screen may be formed on the organic light-emitting device OLED which has been encapsulated (S640).

A touch screen may be formed by forming touch electrodes on a substrate or film made of another transparent insulating material and forming a touch pad connected to the touch electrodes. The touch screen may be placed to face the substrate 210 on which the organic light-emitting device is formed and bonded to the upper part of the organic light-emitting device by using an adhesive member.

The panel of the organic light-emitting device on which the touch screen is formed, is cut and separated into each display panel DP (S650).

In order to increase productivity in the manufacturing process, the display panel DP of an organic light-emitting display apparatus goes through a process of forming multiple unit cells on a single large mother substrate and separating the cells individually. The mother substrate before cutting corresponds to the mother glass panel MP, and the unit cell formed on the mother substrate corresponds to the display panel DP.

As such, the display panel DP of an organic light-emitting display apparatus including the switching and driving thin film transistor TR and the organic light-emitting device including the first electrode 221, the interlayer 220, and the second electrode 222, is completed.

In this regard, as for the method of inspecting the organic light-emitting display apparatus according to embodiments, the impedance of the organic light-emitting device OLED may be measured (S660) before or after operation S630, for example, before or after encapsulation after forming the organic light-emitting device OLED. In other words, according to the method of inspecting the organic light-emitting display apparatus according to an embodiment, the impedance of the organic light-emitting device OLED may be measured by using the inspecting apparatus 100 while being on the mother glass panel MP before being into the unit of display panel DP after the organic light-emitting device OLED is completed on a mother substrate.

Therefore, according to the method of inspecting the organic light-emitting display apparatus according to embodiments, whether the display panel DP is defective may be identified while being on the mother glass panel MP. As described above, according to the method of inspecting the organic light-emitting display apparatus according to embodiments, process efficiency can be improved and process costs can be reduced, compared to a process of the related art in which the characteristics of the display panel DP cut from the mother glass panel MP are measured, or a test unit device is mounted on a mother substrate and characteristics of the corresponding device are measured to identify defects.

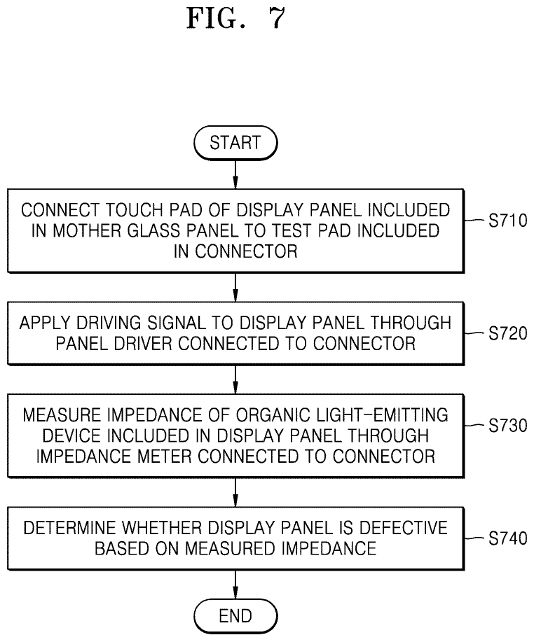

FIG. 7 is a flowchart illustrating a method of inspecting an organic light-emitting display apparatus according to an embodiment;

Referring to FIG. 7, a method of inspecting an organic light-emitting display apparatus according to an embodiment includes connecting a signal pad DP-PD of a display panel DP included in a mother glass panel MP to an inspection pad 111 included in a connector 110 (S710), applying a driving signal to the display panel DP through a panel driver 120 connected to the connector 110 (S720), measuring an impedance of an organic light-emitting device OLED included in the display panel DP through an impedance meter 130 connected to the connector 110 (S730), and determining whether the display panel DP is defective based on the measured impedance (S740).

First, the signal pad DP-PD of the display panel DP included in the mother glass panel MP is connected to the inspection pad 111 included in the connector 110 (S710).

In an embodiment, the connector 110 having the inspection pad 111 is moved onto the mother glass panel MP, and the inspection pad 111 is brought into contact with the signal pad DP-PD of the display panel DP to be inspected, thereby connecting the connector 110 to the display panel DP. In this regard, the inspection pad 111 may be provided to correspond to the arrangement of the display panel DPs on the mother glass panel MP, and inspection pads 111 may respectively come into contact with corresponding signal pads DP-PD. The mother glass panel MP and/or the connector 110 may be moved according to the control signal of the controller 140 and connected to each other, but are not limited thereto.

A driving signal is applied to the display panel DP through the panel driver 120 connected to the connector 110 (S720).

The panel driver 120 may be connected to the connector 110, and the driving signal provided by the panel driver 120 may be transmitted to the display panel DP through the inspection pad 111 and the signal pad DP-PD. In this regard, the driving signal of panel driver 120 may be controlled through the controller 140. The panel driver 120 can individually or selectively drive the organic light-emitting device OLED included in the display panel DP according to the control signal of the controller 140.

The impedance of the organic light-emitting device OLED included in the display panel DP may be measured through the impedance meter 130 connected to the connector 110 (S730).

The impedance meter 130 may be connected to the connector 110. The impedance meter 130 may be electrically connected to the first electrode 221 and the second electrode 222 of the organic light-emitting device OLED through the connector 110. For example, the measurement signal provided by the impedance meter 130 may be transmitted to the organic light-emitting device OLED of the display panel DP through the inspection pad 111 and the signal pad DP-PD. The measurement signal may be a signal in which a measurement alternating current signal provided by the measurement unit 131 and a measurement direct current signal provided by the source unit 132 may be combined with each other at a given ratio through the bias tee 133.

In an embodiment, the impedance meter 130 may obtain a detection signal of an organic light-emitting device corresponding to the measurement signal. By way of example, the measurement unit 131 may obtain an alternating current to which the organic light-emitting device OLED responses in correspondence to the measurement signal, and may calculate impedance from the obtained alternating current.

The impedance meter 130 may measure the impedance of the organic light-emitting device OLED included in the display panel DP on the mother glass panel MP before encapsulation or before performing the touch screen process after the completion of the organic light-emitting device OLED. For example, the connecting the mother glass panel MP and the connector 110 (S610) may be performed at any time between immediately after the organic light-emitting device OLED is completed and before the touchscreen process starts, and the impedance meter 130 may measure the impedance of the organic light-emitting device OLED at any time, such as immediately after deposition of the organic light-emitting device OLED or immediately after encapsulation of the organic light-emitting device OLED, as needed.

Based on the measured impedance, it is determined whether the display panel DP is defective (S740).

The impedance of the organic light-emitting device OLED measured through the impedance meter 130 may be transmitted to the controller 140, and the controller 140 may analyze the impedance to calculate the impedance parameter. In an embodiment, the controller 140 may determine whether the display panel DP is defective by monitoring the calculated impedance parameter.

In an embodiment, the controller 140 may determine whether the display panel DP is defective by calculating the maximum value (Re(Z)ₘₐₓ) of the real part of the measured impedance as an impedance parameter and comparing the same with a reference value. Here, the reference value may be an ideal value measured or expected for an organic light-emitting device in which no impurities are incorporated in an emission layer. However, the disclosure is not limited to the embodiment, and the reference value may be a value determined using data accumulated through multiple measurements.

In an embodiment, the controller 140 may determine whether the display panel DP is defective by calculating, as an impedance parameter, a waveform of the graph of the real part according to the voltage change of the measured impedance and comparing the same with a reference value. The reference value may be an ideal value measured or expected for an organic light-emitting device in which pixel lateral current does not occur, but is not limited thereto.

The controller 140 may determine the display panel DP to be defective in case that the impedance parameter is outside a preset range with respect to the reference value. The controller 140 may determine whether the display panel DP is defective and provide a result report.

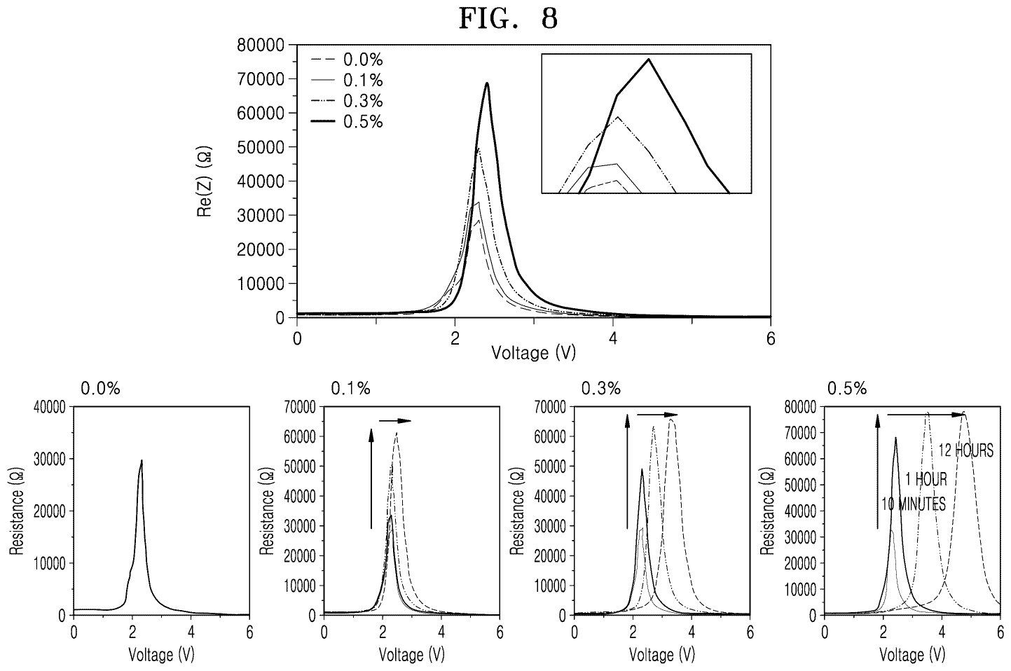

FIG. 8 is a graph showing the change in the impedance real part Re(Z) according to the incorporation of impurities. Referring to FIG. 8, the upper graph is a graph of the impedance real part Re(Z) according to voltage in case that impurities are incorporated into an emission layer of an organic light-emitting device at concentrations of about 0.0%, about 0.1%, about 0.3%, and about 0.5%, and the lower four graphs show graphs of the impedance real part Re(Z) according to voltage in case that each condition is aged at a given brightness for about 10 minutes, about 1 hour, and about 12 hours.

Referring to FIG. 8 which is the graph of the impedance real part Re(Z) according to voltage, the maximum value (Re(Z)ₘₐₓ) is increased as the concentration of the impurities incorporated in the emission layer of the organic light-emitting device is increased. As the organic light-emitting device OLED ages, the change in the maximum value (Re(Z)ₘₐₓ) of the impedance real part is increased.

Therefore, the incorporation of impurities in organic light-emitting devices was able to be identified by monitoring the maximum value Re(Z)ₘₐₓ of the impedance real part as an impedance parameter in the manufacturing process for an organic light-emitting display apparatus, and whether the organic light-emitting device OLED is defective could be quickly determined in-FAB, leading to smaller manufacturing costs and time and higher reliability of produced organic light-emitting display apparatuses.

To detect a change according to incorporation with impurities by using the maximum value (Re(Z)ₘₐₓ) of the impedance real part as an impedance parameter, the inspecting apparatus 100 of the organic light-emitting display apparatus may measure an impedance by applying an alternating current signal having a relatively high frequency (for example, about 1000 Hz). The graph of the impedance real part Re(Z) according to voltage shows the maximum value (Re(Z)ₘₐₓ) at such a voltage that the organic light-emitting device OLED is driven with high brightness. Accordingly, the inspecting apparatus 100 measures the impedance by using the alternating current signal having a relatively high frequence, more accurate measurement results may be obtained and the accuracy in determining defects according to the incorporation of impurities is improved.

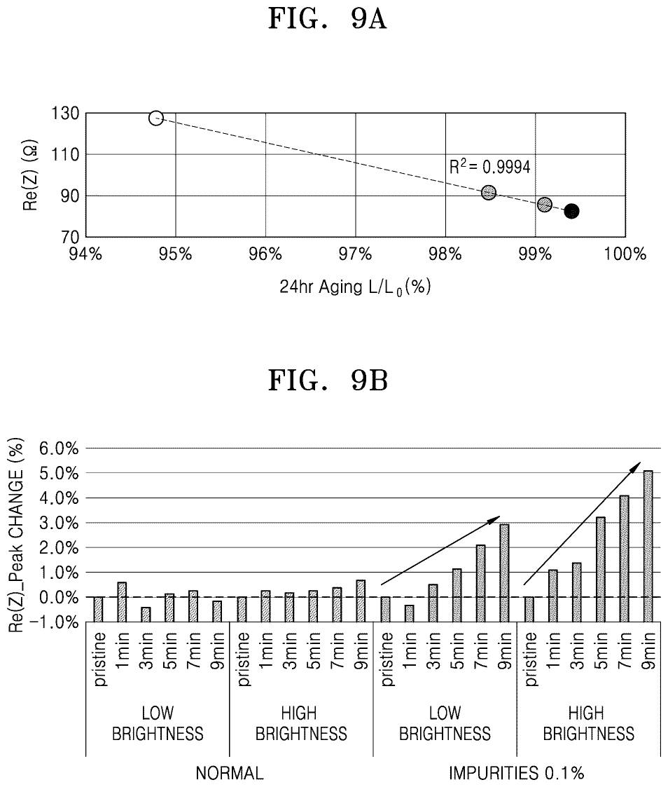

FIGS. 9A and 9B are graphs showing a change in the maximum value (Re(Z)ₘₐₓ) of the impedance real part according to aging. FIG. 9A shows a graph showing the consistency of the maximum value (Re(Z)ₘₐₓ) of the impedance real part and the change in the lifespan of an organic light-emitting device, and FIG. 9B shows a graph showing the change in the maximum value (Re(Z)ₘₐₓ) of the impedance real part according to aging in an organic light-emitting device including impurities.

Referring to FIG. 9A, in case that the display panel DP was aged while being on the mother glass panel MP and the impedance (Z) was measured and the maximum value (Re(Z)ₘₐₓ) of the impedance real part, which is one of impedance parameters, was calculated, it was found that the maximum value (Re(Z)ₘₐₓ) of the impedance real part has a linear correlation with the brightness ratio (L/Lo) corresponding the change in the lifespan of the organic light-emitting device, and the coefficient of determination (R²) was confirmed to be 0.9994, with about 99% consistency.

Also, referring to FIG. 9B, in case that aging was performed on a display panel DP in a normal state without incorporation of impurities and a display panel DP including about 0.1% of impurities, the impedance Z was measured, and the change in the maximum value (Re(Z)ₘₐₓ) of the impedance real part was calculated, it was found that, compared to the display panel DP in a normal state, the display panel DP incorporated with impurities showed a great change in the maximum value (Re(Z)ₘₐₓ) of the impedance real part and as aging is performed, the maximum value (Re(Z)ₘₐₓ) of the impedance real part was increased and the change during high-brightness driving was greater than that during low-brightness driving.

Therefore, it can be seen that the maximum value (Re(Z)ₘₐₓ) of the impedance real part can be used as a parameter that well represents the characteristics that change due to the incorporation of impurities in an organic light-emitting device. The inspecting apparatus 100 of the organic light-emitting display apparatus according to embodiments of the disclosure measures the impedance Z while being in the mother glass panel MP and performs monitoring by using the maximum value (Re(Z)ₘₐₓ) of the impedance real part calculated from the measured impedance Z as an impedance parameter. As a result, defects due to impurities in organic light-emitting devices can be quickly and accurately screened in advance.

FIGS. 10A through 10E are schematic diagrams for explaining pixel lateral current of an organic light-emitting device. FIG. 10A is a schematic diagram showing the normal-state driving of the organic light-emitting device, FIG. 10B is a schematic diagram showing a state in which a pixel lateral current occurs in the organic light-emitting device. FIGS. 10C through 10E are schematic diagrams showing pixels of the display panel DP emit red (R) light, green (G) light, and blue B light.

Referring to FIG. 10B compared to FIG. 10A, in case that the organic light-emitting device is driven at low gray levels, the pixel lateral current may occur in a horizontal direction of the organic light-emitting device and at this time, adjacent pixels that are not required to emit light may emit light.

For example, as shown in FIG. 10A, a blue B pixel may be turned on according to the difference between the high potential voltage VDD and the low potential voltage VSS, and a red (R) pixel may be turned off according to the initialization voltage Avint. As shown in FIG. 10B, when the blue B pixel is driven with a predetermined low voltage, the pixel lateral current may be generated toward the red (R) pixel, which has a lower resistance than the blue B pixel, so that the red (R) pixel may be turned on. In case that driven at a low voltage, the pixel lateral current may occur in a pixel that emits blue B light, causing adjacent red (R) pixels to emit light. In case that an organic light-emitting device is driven using low driving voltages, the pixel lateral current may occur in adjacent organic light-emitting devices due to the difference in resistance between respective organic light-emitting devices.

In case that the pixel lateral current occurs in the display panel DP, color mixing occurs and color coordinate fluctuations may occur.

For example, as shown in FIG. 10C, if only the red (R) pixel is driven with a low driving voltage, the pixel lateral current does not occur, but as shown in FIG. 10D, if only the green (G) pixel is driven with a low driving voltage, the pixel lateral current may occur toward the adjacent red (R) pixel, causing the red (R) pixel to emit light as well. As shown in FIG. 10E, if the blue B pixel is emitting light with a low driving voltage, the pixel lateral current may occur toward the adjacent red (R) pixel and the adjacent green (G) pixel, causing blue B, green (G), and red (R) light to mix.

In an embodiment, in case that this pixel lateral current occurs in a low brightness area, black brightness may be increased. In order to detect defects due to such a pixel lateral current, the inspecting apparatus 100 according to embodiments may calculate the impedance parameter and determine the defect.

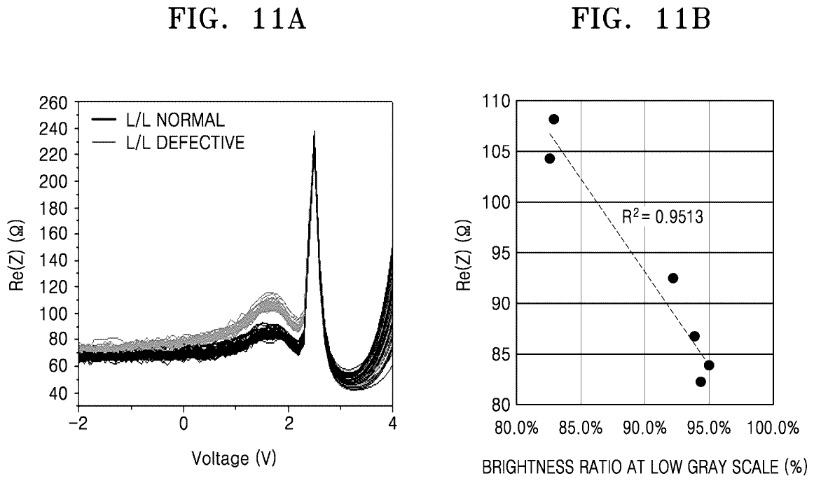

FIGS. 11A and 11B are graphs showing the change in the impedance real part Re(Z) according to a pixel lateral current caused by a change in a panel process. FIG. 11A shows a graph of the impedance real part Re(Z) according to voltage in the case where the pixel lateral current occurs (L/L defective) and the case where the pixel lateral current does not occur (L/L normal). FIG. 11B is a graph showing the consistency of the impedance real part Re(Z) and the pixel lateral current.

One of the causes of pixel lateral current is an abnormality in the interface state of the anode due to changes in the panel process. Referring to the graph of the impedance real part Re(Z) according to voltage in case that the impedance Z is measured with respect to an abnormal panel in which an abnormal interface state of an anode occurs, as shown in FIG. 11A, it can be seen that the value of the impedance real part Re(Z) is increased in a defective panel, compared to a normal panel. In this regard, in case that the pixel lateral current occurs (L/L defective), compared to in case that the pixel lateral current does not occur (L/L normal), the area around the first peak value in the graph of the impedance real part Re(Z) according to voltage is increased.

As shown in FIG. 11B, the impedance Z was measured for a panel in which the pixel lateral current occurred due to a change in the panel process, and the impedance real part Re(Z) was calculated. As a result, it can be seen that value of the impedance real part Re(Z) has a linear correlation with the brightness ratio at low gray levels corresponding to the pixel lateral current, and the determination coefficient (R²) was 0.9513, equivalent to the consistency of about 95%. Therefore, it can be seen that the impedance real part Re(Z) value at a given voltage can be used as an impedance parameter to detect the pixel lateral current occurring due to the change in the panel process. In this regard, a voltage at which the value of impedance real part Re(Z) is changed due to the lateral current is determined as the given voltage.

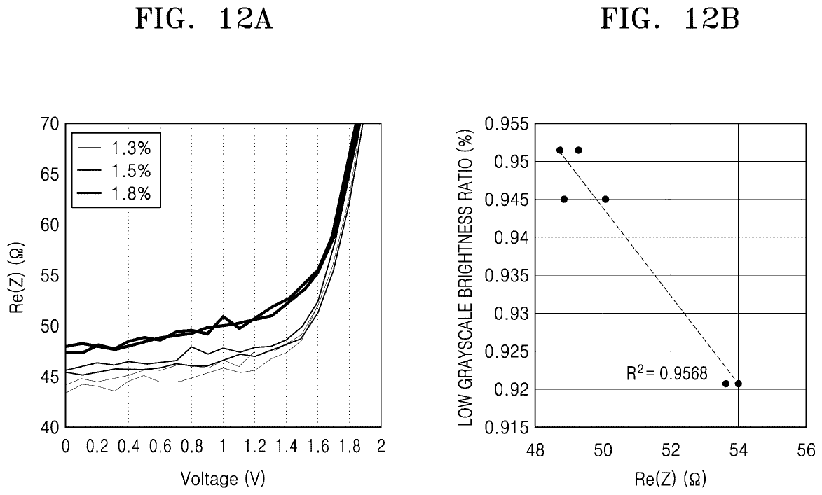

FIGS. 12A and 12B are graphs showing the change in the impedance real part Re(Z) according to the pixel lateral current caused by p-type doping. FIG. 12A shows a graph of the impedance real part Re(Z) according to voltage for each display panel in which the p-type doping concentration was increased to about 1.3%, about 1.5%, and about 1.8%, and FIG. 12 is a graph showing the consistency of the impedance real part Re(Z) and the pixel lateral current.

Another cause of the pixel lateral current is an increase in conductivity due to an increase in p-type doping concentration. In case that the impedance Z is measured for each display panel with the p-type doping concentration increased to about 1.3%, about 1.5%, and about 1.8%, and the impedance real part Re(Z) according to the voltage is plotted on a graph, it can be seen that the value of the impedance real part Re(Z) is increased as the p-type doping concentration is increased, as shown in FIG. 12A. In this regard, it can be seen that the value of the real part of the impedance Re(Z) is increased significantly in case that the p-type doping concentration is about 1.8% compared to in case that the p-type doping concentration is about 1.3% and about 1.5%. This corresponds to the increase in the pixel lateral current as the p-type doping concentration is increased.

As shown in FIG. 12B, the impedance Z was measured for each panel while increasing the p-type doping concentration, and the impedance real part Re(Z) was calculated. As a result, it can be seen that a value of the impedance real part Re(Z) has a linear correlation with the brightness ratio at low gray levels corresponding to the pixel lateral current, and the determination coefficient (R²) was 0.9568, equivalent to the consistency of about 95%. Therefore, it can be seen that the impedance real part Re(Z) value at a given voltage can be used as an impedance parameter to detect the pixel lateral current according to an increase in p-type doping concentration. In this regard, a voltage at which the value of impedance real part Re(Z) is changed due to the lateral current is determined as the given voltage.

As such, in the manufacturing process of an organic light-emitting display device, a defect in which the pixel lateral current occurs in a display panel DP can be detected by monitoring the value of the impedance real part Re(Z) at a given voltage as an impedance parameter. Also, manufacturing costs and time can be saved by quickly determining display panel DP defects on the manufacturing line (in-FAB), and reliability of the organic light-emitting display apparatus produced can be ensured.

On the other hand, in the case where the change in the pixel lateral current is detected by using the impedance real part Re(Z) at a given voltage as an impedance parameter, the inspecting apparatus 100 of the organic light-emitting display apparatus may measure the impedance by applying an alternating current signal having a relatively low frequency (for example, a frequency of about 500 Hz). In the case of driving at low gray levels, at which the pixel lateral current is generated, the accuracy of measured values in the low frequency region may be improved. Accordingly, the inspecting apparatus 100 can obtain more accurate measurement results by measuring the impedance using an alternating current signal with a relatively low frequency, and the accuracy of determining defects caused by the occurrence of pixel lateral current can be improved.

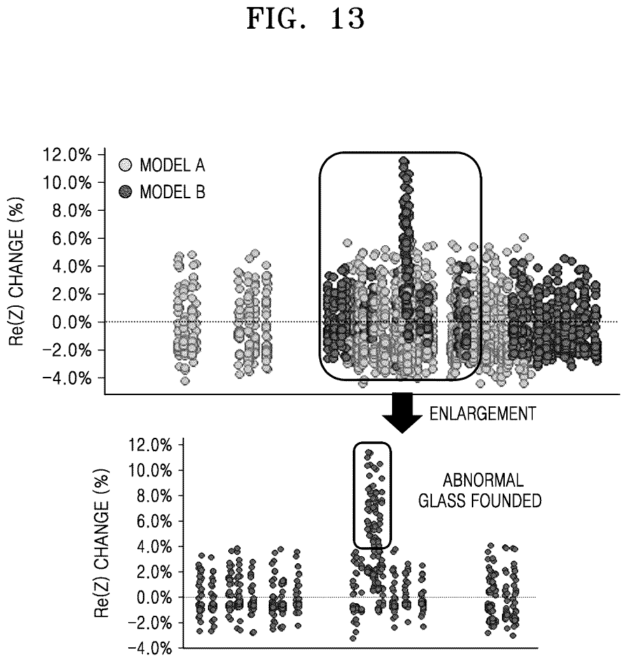

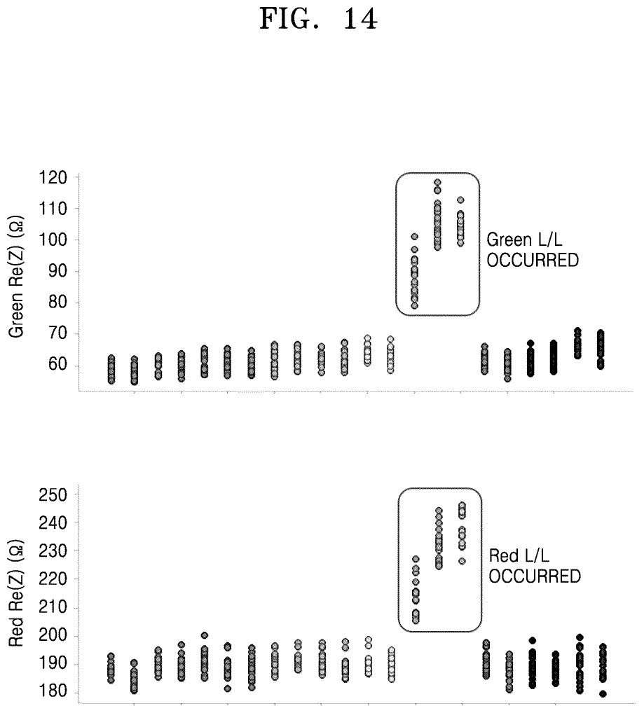

FIG. 13 is a graph showing the results of time-series monitoring of the change in the impedance real part Re(Z) according to aging, and FIG. 14 is a graph showing the results of time-series monitoring of impedance real part Re(Z) according to the occurrence of the pixel lateral current.

Referring to FIGS. 13 and 14, the x-axis corresponds to the measurement time series, and the y-axis corresponds to the impedance parameter. In an embodiment, the data in the vertical direction is data corresponding to one mother glass panel MP measured at the same time.

Referring to FIG. 13, the impedance Z is measured during mass production of a panel by using the inspecting apparatus 100 according to an embodiment, and the maximum value of the impedance real part Re(Z)ₘₐₓ is monitored as the impedance parameter to test the performance of the inspecting apparatus 100. As can be seen in FIG. 13, most of the data is distributed symmetrically up and down around the change amount of about 0%, and from among the mother glass panels MP of model B as compared with model A, a given mother glass panel MP had a singularity. From this result, it was identified that the corresponding mother glass panel MP of model B is defective due to the inflow of impurities.

Referring to FIG. 14, by using the inspecting apparatus 100 according to an embodiment, the impedance Z during mass production of a panel was measured and the impedance real part Re(Z) value at a given voltage was monitored as an impedance parameter to test the performance of the inspecting apparatus 100. As can be seen in FIG. 13, most of the data shows a similar pattern, but a given mother glass panel MP had a singularity that deviates from this pattern and the corresponding mother glass panel MP had the defect of occurrence of pixel lateral current.

In this way, by using the inspecting apparatus 100 according to an embodiment, the impedance Z is measured, and the maximum value Re(Z)ₘₐₓ of the impedance real part or an impedance real part Re(Z) at a given voltage are monitored as impedance parameters. As a result, the defects in display panels DP could be quickly, accurately detected while being on the mother glass panel MP.

As described above, according to the inspecting apparatus 100 and the inspection method for an organic light-emitting display apparatus according to an embodiment, the impedance Z of the organic light-emitting device can be measured while being on the mother glass panel MP immediately after forming the organic light-emitting device during the manufacturing process of the display panel DP, and impedance parameters are calculated and based thereon, defects of the display panel DP can be detected. According to the inspecting apparatus 100 and the inspection method for an organic light-emitting display apparatus according to an embodiment, defects can be monitored while being in the mother glass panel MP. Accordingly, process efficiency can be increased and process costs can be reduced.

Each of the embodiments described above can be implemented independently, and the structure of respective embodiments can be applied in combination to other embodiments.

As such, the disclosure has been described with reference to the embodiments shown in the drawings, but these are illustrative, and those skilled in the art will understand that various modifications and equivalent other embodiments are possible therefrom. Therefore, the true scope of technical protection of the disclosure should be determined by the technical spirit of the attached claims.

Given implementations described in the embodiments are examples and do not limit the scope of the embodiments in any way. In an embodiment, in case that there is no given wordings such as “essential,” “important,” etc. recited, it may not be a necessary component for the application of the disclosure.

In the specification of the embodiment (for example in the claims), the use of the term “the” and similar referential terms thereto may refer to both the singular and the plural. In case that a range is described in an embodiment, the disclosure includes the application of individual values in the range (unless there is a statement to the contrary), and is the same as describing each individual value constituting the range in the detailed description. Finally, unless the order of the operations constituting the method according to the embodiments is clearly stated or there is no description to the contrary, the operations may be performed in an appropriate order. The embodiments are not necessarily limited by the order of description of the operations above. The use of all examples or illustrative terms in the embodiments is for explaining the embodiments in detail, and the scope of the embodiments is not limited by the examples or illustrative terms unless limited by the claims. In an embodiment, those skilled in the art will recognize that various modifications, combinations and changes may be made depending on design conditions and factors within the scope of the appended claims or their equivalents.

In embodiments, the impedance of an organic light-emitting device can be measured while being in a mother glass panel. Through this, defects in the display panel can be immediately detected during the process of forming a display panel, and process efficiency can be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that various changes in form and details may be made therein without departing from the spirit and scope and as defined by the following claims.

What is claimed is:

1. An inspecting apparatus for an organic light-emitting display apparatus, the inspecting apparatus comprising:
a connector including an inspection pad electrically connected to a signal pad of a display panel included in a glass panel;
a panel driver electrically connected to the connector and supplying a driving signal to drive the display panel; and
an impedance meter electrically connected to the connector and that measures an impedance of an organic light-emitting device included in the display panel.

2. The inspecting apparatus of claim 1, wherein
the organic light-emitting device includes a first electrode, an interlayer, and a second electrode, and
the impedance meter is electrically connected to the first electrode and the second electrode of the organic light-emitting device to measure the impedance of the interlayer of the organic light-emitting device.

3. The inspecting apparatus of claim 1, wherein
the impedance meter measures the impedance by applying a measurement direct current signal and a measurement alternating current signal to the organic light-emitting device.

4. The inspecting apparatus of claim 3, wherein
the impedance meter comprises:
a measurement member that applies the measurement alternating current signal and obtains an impedance corresponding to the measurement alternating current signal;
a source member that applies the measurement direct current signal; and
a bias tee connecting the measurement member and the source member to the connector.

5. The inspecting apparatus of claim 4, wherein
the bias tee combines the measurement alternating current signal and the measurement direct current signal and provides a combined result to the organic light-emitting device.

6. The inspecting apparatus of claim 1, further comprising:
a controller that determines whether the display panel is defective based on the obtained impedance.

7. The inspecting apparatus of claim 6, wherein
the controller calculates an impedance parameter of the organic light-emitting device from the impedance and determines whether the display panel is defective by using the calculated impedance parameter.

8. The inspecting apparatus of claim 7, wherein
the impedance parameter is defined as a maximum value in a graph showing a real part of the impedance of the organic light-emitting device as a function with respect to voltage.

9. The inspecting apparatus of claim 7, wherein
the controller determines whether the display panel is defective by using an amount of change in the impedance parameter according to aging.

10. The inspecting apparatus of claim 1, wherein
the impedance meter measures the impedance of the organic light-emitting device before being cut into display panel units after the organic light-emitting device is completed on the glass panel.

11. A method of inspecting an organic light-emitting display apparatus comprising:
electrically connecting a signal pad of a display panel included in a glass panel to an inspection pad included in a connector;
applying a driving signal to the display panel through a panel driver electrically connected to the connector;
measuring an impedance of an organic light-emitting device included in the display panel by using an impedance meter electrically connected to the connector; and
determining whether the display panel is defective based on the measured impedance.

12. The method of claim 11, wherein
the organic light-emitting device includes a first electrode, an interlayer, and a second electrode, and
the impedance meter is electrically connected to the first electrode and the second electrode of the organic light-emitting device to measure the impedance of the interlayer of the organic light-emitting device.

13. The method of claim 11, wherein
the impedance meter measures the impedance by applying a measurement direct current signal and a measurement alternating current signal to the organic light-emitting device.

14. The method of claim 13, wherein
the impedance meter comprises:
a measurement member that applies the measurement alternating current signal and obtains an impedance corresponding to the measurement alternating current signal;
a source member that applies the measurement direct current signal; and
a bias tee electrically connecting the measurement member and the source member to the connector.

15. The method of claim 14, wherein
the bias tee combines the measurement alternating current signal and the measurement direct current signal and provides a combined result to the organic light-emitting device.

16. The method of claim 11, wherein
the determining whether the display panel is defective comprises calculating an impedance parameter of the organic light-emitting device from the impedance, and determining whether the display panel is defective by using the calculated impedance parameter.

17. The method of claim 16, wherein
the impedance parameter is defined as a maximum value in a graph showing a real part of the impedance of the organic light-emitting device as a function with respect to voltage.

18. The method of claim 17, wherein
whether the display panel is defective is determined based on a change in the impedance parameter according to aging.

19. The method of claim 16, wherein
the determining whether the display panel is defective comprises sequentially obtaining the impedance parameter from a plurality of sequentially deposited glass panels and determining that the display panel included in a corresponding glass panel is defective in case that the impedance parameter deviates from a given reference value.

20. The method of claim 11, wherein
the measuring of the impedance of the organic light-emitting device is performed before the glass panel is cut into display panel units after the organic light-emitting device is completed on the glass panel.
